(19) United States
(12) Patent Application Publication
(10) Pub. No.: US 2008/0233712 A1
(43) Pub. Date: Sep. 25, 2008

(54) METHOD OF MANUFACTURING DEVICE

(75) Inventor: Kazuma Sekiya, Ota-Ku (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/041,024

(22) Filed: Mar. 3, 2008

(30) Foreign Application Priority Data
Mar. 22, 2007 (JP) 2007-74481

(51) Int. Cl. H01L 21/78

(52) U.S. Cl. 438/462; 257/E21.599

(57) ABSTRACT

A method of manufacturing a device includes the steps of forming dividing grooves with a predetermined depth along planned dividing lines of a wafer, then grinding the backside surface of the wafer to expose the dividing grooves on the back side and to divide the wafer into individual devices, mounting a UV-curing adhesive film to the backside surface of the wafer divided into the individual devices, adhering the adhesive film side of the wafer to a dicing tape attached to an annular frame, radiating UV rays from the face side of the wafer to cure the regions of the adhesive film which correspond to the dividing grooves, expanding the dicing tape to exert tensile forces on the adhesive film, so as to split the adhesive film into the individual devices, with the cured regions of the adhesive film as starting points of splitting, and releasing the device from the dicing tape and thereby picking up the device.

### BACKGROUND OF THE INVENTION

1. Field of the Invention

The present invention relates to a method of manufacturing a device by which a wafer provided with devices formed in a plurality of regions demarcated by planned dividing lines formed in a lattice form in a face-side surface thereof is divided along the planned dividing lines into individual devices and a die-bonding adhesive film is attached to the back side of each of the devices.

2. Description of the Related Art

For example, in the manufacturing process of a semiconductor device, devices such as ICs and LSIs are formed in a plurality of regions demarcated by streets (planned dividing lines) formed in a lattice pattern in the face-side surface of a semiconductor wafer having a roughly circular disk-like shape, and the regions with the devices formed therein are divided along the planned dividing lines, to thereby manufacture the individual devices. As a dividing apparatus for dividing the semiconductor wafer, a cutting apparatus called dicing apparatus is normally used. The cutting apparatus cuts the semiconductor wafer along the planned dividing lines by a cutting blade having a thickness of about 40 μm. The devices divided in this manner are packaged, to be used widely in electric apparatuses such as cellular phones, personal computers, etc.

To the backside surface of each of the devices thus divided individually, a die-bonding adhesive film called die attachment film which is formed of an epoxy resin or the like and having a thickness of 70 to 80 μm is attached, and the device is bonded to a die bonding frame for supporting the device through the adhesive film by heating. The die-bonding adhesive film is attached to the backside surfaces of the devices by, for example, a method in which the adhesive film is adhered to the backside surface of the semiconductor wafer, the semiconductor wafer is adhered to the dicing tape through the adhesive film, and the adhesive film is cut together with the semiconductor wafer by a cutting blade along planned dividing lines formed in the face-side surface of the semiconductor wafer, to thereby obtain the devices each with the adhesive film attached to the backside surface thereof (refer to, for example, Japanese Patent Laid-Open No. 2000-182995).

In recent years, electric apparatuses such as cellular phones and personal computers have been desired to be reduced in weight and size, and there is a demand for thinner devices. As a technology for dividing devices in a thinner form, a dividing technology called “dicing-before-grinding” has been put to practical use. The dicing-before-grinding method is a technology in which dividing grooves are formed in a semiconductor wafer in a predetermined depth (a depth corresponding to the finished thickness of devices) along planned dividing lines from the face side of the semiconductor wafer, and then the backside surface of the semiconductor wafer provided with the dividing grooves in the face-side surface thereof is ground to expose the dividing grooves on the back side, thereby dividing the semiconductor wafer into the individual devices. By the dicing-before-grinding method, the devices can be machined to have a thickness of 100 μm or below.

However, in the case of dividing a semiconductor wafer into individual devices by the dicing-before-grinding technique, the dividing grooves are formed in the semiconductor wafer in a predetermined depth along the planned dividing lines from the face side of the semiconductor wafer and, thereafter, the backside surface of the semiconductor device is ground to expose the dividing grooves on the back side. Therefore, a die-bonding adhesive film cannot be preliminarily attached to the backside surface of the semiconductor wafer. As a result, bonding to a die bonding frame the device manufactured by the dicing-before-grinding method has to be carried out while inserting a bonding agent between the device and the die bonding frame, which makes it very difficult to smoothly perform the bonding work.

To solve such a problem, there has been proposed a semiconductor device manufacturing method in which a die-bonding adhesive film is attached to the backside surface of the semiconductor wafer divided into individual devices by the dicing-before-grinding technique, the semiconductor wafer is adhered to a dicing tape through the adhesive film, and then the parts of the adhesive film which are exposed in the gaps between the devices are chemically etched away; besides, there has also been proposed a semiconductor device manufacturing method in which the parts of the adhesive film which are exposed in the gaps between the devices are irradiated with a laser beam through the gap from the face side of the devices, to remove the parts of the adhesive film which are exposed in the gaps (refer to, for example, Japanese Patent Laid-Open No. 2002-118081).

Incidentally, in order to cut the adhesive film by irradiation with a laser beam, the adhesive film has to be irradiated with a laser beam having such a wavelength as to permit absorption into the adhesive film (for example, 355 nm) and a mean output of about 2 W. Since the laser beam with a mean output of about 2 W is comparatively strong in output, irradiation of the adhesive film with the laser beam causes scattering of debris, and the scattered debris would adhere to the surfaces of the devices, thereby lowering the device quality.

### SUMMARY OF THE INVENTION

Accordingly, it is an object of the present invention to provide a method of manufacturing a device by which a die-bonding adhesive film can be easily attached to a backside surface of each of devices divided by a dicing-before-grinding method, without lowering the quality of the devices.

In accordance with an aspect of the present invention, there is provided a method of manufacturing a device, for dividing a wafer provided with devices formed in a plurality of regions demarcated by planned dividing lines formed in a lattice pattern in a face-side surface thereof, into individual devices, the method including: a wafer dividing step of forming dividing grooves in a predetermined depth along the planned dividing lines from the face side of the wafer, then grinding a backside surface of the wafer to expose the dividing grooves on the back side of the wafer and dividing the wafer into the individual devices; an adhesive film attaching step of attaching a UV-curing adhesive film to the backside surface of the wafer divided into the individual devices; a wafer supporting step of adhering the adhesive film side of the wafer with the adhesive film attached thereto to a surface of a dicing tape attached to an annular frame; an adhesive film curing step of radiating UV rays from the face side of the wafer adhered to the dicing tape so as to irradiate the adhesive film with the UV rays through the dividing grooves formed in the wafer and thereby to cure those regions of the adhesive tape which correspond to the dividing grooves; an adhesive film splitting step of, after the adhesive film curing step, expanding the dicing tape so as to exert a tension on the adhesive film and to split the adhesive film along the devices, with the cured regions of the adhesive film as starting points of splitting; and a pick-up step of, after the adhesive film splitting step, releasing from the dicing tape, and picking up, each of the devices to which the adhesive tape divided on the device basis has been attached.

According to the present invention, after the adhesive film curing step of irradiating the adhesive film attached to the backside surface of the wafer with UV rays through the dividing grooves, formed in the wafer by the wafer splitting step, so as to cure those regions of the adhesive film which correspond to the dividing grooves is carried out, the dicing tape with the adhesive film adhered thereto is expanded so as to exert a tension on the adhesive film and to split the adhesive film along the devices, with the cured regions of the adhesive film as starting points of splitting. Therefore, generation of debris, as in the method of cutting the adhesive film by irradiation with a laser beam, is obviated. Accordingly, it is possible to preclude a lowering in device quality which might be caused by adhesion of debris to the surfaces of the devices.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a semiconductor wafer as a wafer;

FIGS. 2A and 2B illustrate a dividing groove forming step in a wafer splitting step of the method of manufacturing a device based on the present invention;

FIGS. 3A and 3B illustrate a protective member adhering step in the wafer splitting step of the method of manufacturing a device based on the present invention;

FIGS. 4A to 4C illustrate a dividing groove exposing step in the wafer splitting step of the method of manufacturing a device based on the present invention;

FIGS. 5A and 5B illustrate an adhesive film attaching step of the method of manufacturing a device based on the present invention;

FIG. 6 illustrates a wafer supporting step of the method of manufacturing a deice based on the present invention;

FIGS. 7A and 7B illustrate an embodiment of an adhesive film curing step of the method of manufacturing a device based on the present invention;

FIG. 8 illustrates another embodiment of the adhesive film curing step of the method of manufacturing a device based on the present invention;

FIG. 9 is a perspective view of a picking-up apparatus for carrying out an adhesive film splitting step and a pick-up step of the method of manufacturing a device based on the present invention;

FIGS. 10A and 10B illustrate the adhesive film splitting step of the method of manufacturing a device based on the present invention; and

FIG. 11 illustrates the pick-up step of the method of manufacturing a device based on the present invention.

### DETAILED DESCRIPTION OF THE PREFERRED EMBODIMENTS

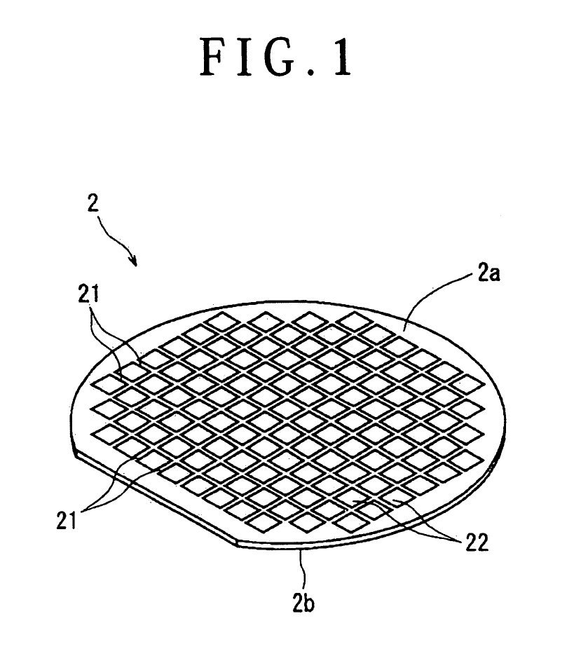

Now, a preferred embodiment of the method of manufacturing a device based on the present invention will be described in detail below, referring to the attached drawings. FIG. 1 shows a perspective view of a semiconductor wafer as a wafer in the invention. The semiconductor wafer 2 shown in FIG. 1 is, for example, a silicon wafer having a thickness of 600 μm, which is provided in its face-side surface 2a with a plurality of planned dividing lines 21 in a lattice pattern. On the face-side surface 2a of the semiconductor wafer 2, in addition, devices 22 such as ICs and LSIs are formed in a plurality of regions demarcated by the plurality of planned dividing lines 21 formed in the lattice pattern.

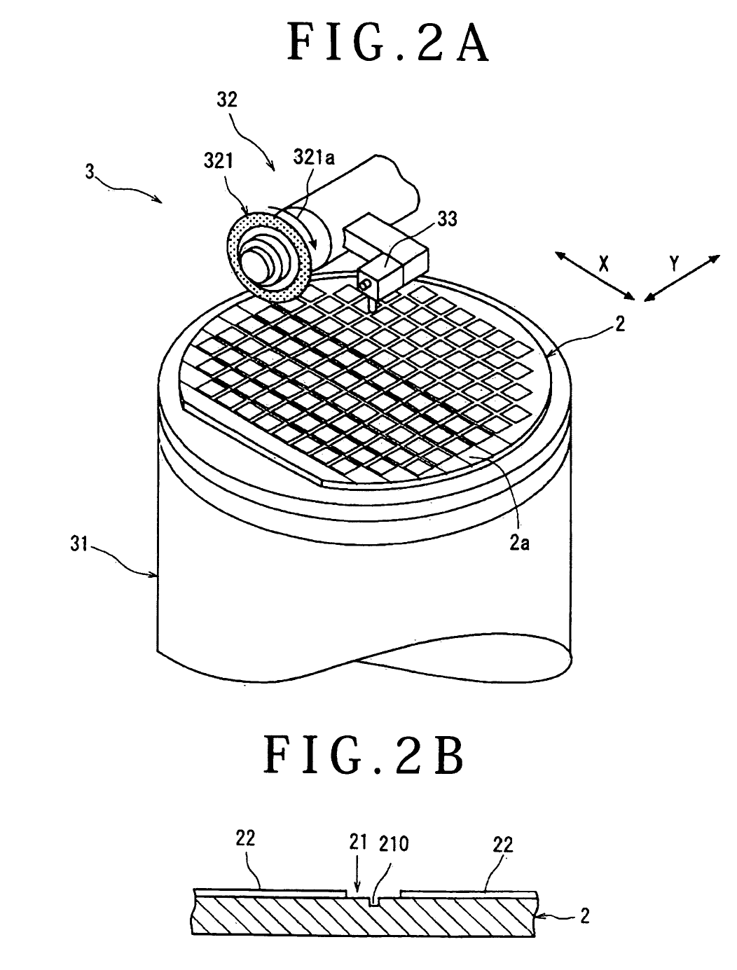

The semiconductor wafer 2 shown in FIG. 1 is divided into the individual devices 22 by carrying out a wafer dividing step based on the so-called dicing-before-grinding method. In the wafer dividing step based on the dicing-before-grinding technique, first, dividing grooves with a predetermined depth (a depth corresponding to a finished thickness of the devices) are formed along the planned dividing lines 21 formed in the face-side surface 2a of the semiconductor wafer 2 (dividing groove forming step). The dividing groove forming step is carried out by use of a cutting apparatus 5 shown in FIG. 2A. The cutting apparatus 2 shown in FIG. 2A includes a chuck table 31 equipped with suction holding means, cutting means 32 equipped with a cutting blade 321, and imaging means 33. In carrying out the dividing groove forming step, the semiconductor wafer 2 is mounted on the chuck table 31, with its face-side surface 2a up. Then, suction means (not shown) is operated to thereby hold the semiconductor wafer 2 on the chuck table 31. The chuck table 31 with the semiconductor wafer 2 suction held thereon in this manner is positioned into a position directly under the imaging means 33 by a cutting feeding mechanism (not shown).

When the chuck table 31 is positioned in the position just under the imaging means 33, an alignment work is carried out in which a cutting region, where to form a dividing groove, of the semiconductor wafer 2 is detected by the imaging means 33 and control means (not shown). Specifically, the imaging means 33 and the control means (not shown) execute image processing such as pattern matching for matching the positions of the planned dividing line 21 formed in the semiconductor wafer 2 along a predetermined direction 2 and the cutting blade 321, so as to perform alignment of the cutting region (alignment step). In addition, for the planned dividing line 21 formed in the semiconductor wafer 2 to extend perpendicularly to the predetermined direction, also, similar alignment of the cutting region is carried out.

After the alignment of the cutting region of the semiconductor wafer 2 held on the chuck table 31 is conducted as above, the chuck table 31 holding the semiconductor wafer 2 thereon is moved to a cutting starting position of the cutting region. Then, the cutting blade 321 is moved downwards while being rotated in the direction of arrow 321a in FIG. 2A, to perform a predetermined amount of cutting-in feed. The cutting-in feed position in this case is so set that an outer peripheral edge of the cutting blade 321 reaches a depth position (for example, 110 μm) corresponding to the finished thickness of the device from the face-side surface of the semiconductor wafer 2.

After the cutting-in feed of the cutting blade 321 is thus conducted, the chuck table 31 is put into cutting feed in the direction of arrow X in FIG. 2A while keeping the cutting blade 321 in rotation, whereby a dividing groove 210 with a depth (for example, 110 μm) corresponding to the finished thickness of the device is formed along the planned dividing line 21 as shown in FIG. 2B (dividing groove forming step). This dividing groove forming step is carried out along all the planned dividing lines 21 formed in the semiconductor wafer 2.

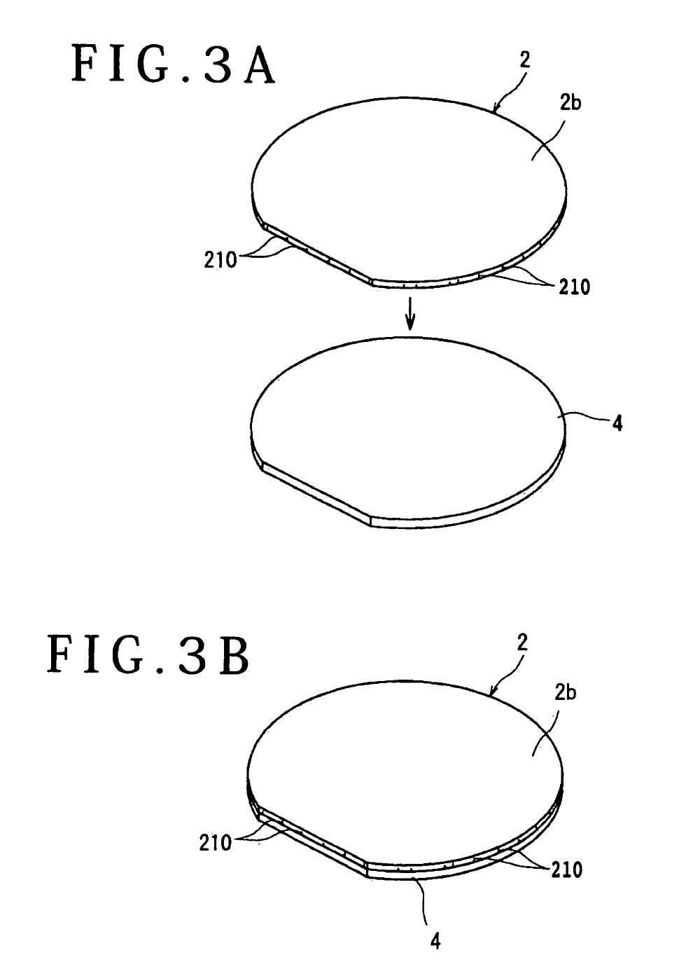

After the dividing grooves 210 with the predetermined depth are formed in the face-side surface 2a of the semiconductor wafer 2 along the planned dividing lines 21 by the dividing groove forming step described above, a protective member 4 for grinding is adhered to the face-side surface 2a (the surface on which the devices 22 are formed) of the semiconductor wafer 2 as shown in FIGS. 3A and 3B (protective member adhering step). Incidentally, the protective member 4, in the embodiment shown, includes a polyolefin sheet having a thickness of 150 μm.

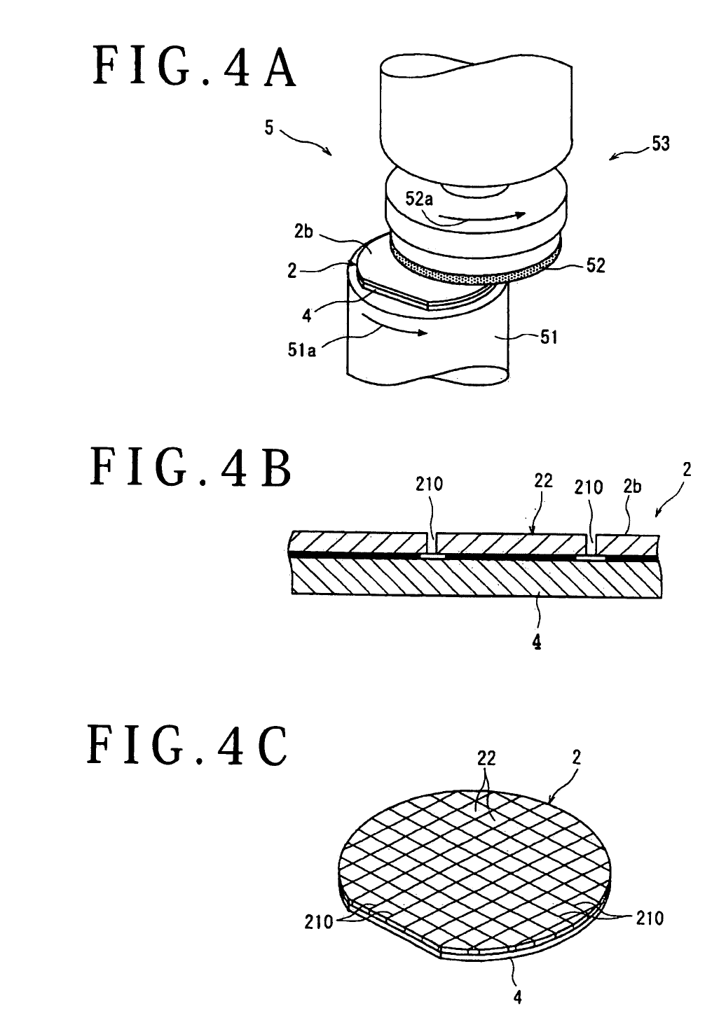

Next, a backside surface 2b of the semiconductor wafer 2 carrying the protective member 4 adhered to its face-side surface 2a thereof is ground so as to expose the dividing grooves 210 at the backside surface 2b, thereby dividing the semiconductor wafer 2 into individual devices (dividing groove exposing step). The dividing groove exposing step is carried out by a chuck table 51 and a grinding apparatus 5 including grinding means 53 having a grindstone 52, as shown in FIG. 4A. Specifically, the semiconductor wafer 2 is held on the chuck table 51 with its backside surface 2b up, the chuck table 51 is kept rotating, for example, at a speed of 300 rpm in the direction of arrow 51a, the grindstone 52 of the grinding means 53 is rotated at 6,000 rpm in the direction of arrow 52a, and the grindstone 52 is brought into contact with the backside surface 2b of the semiconductor wafer 2, thereby grinding the backside surface 2b until the grinding grooves 210 are exposed at the backside surface 2b as shown in FIG. 4B. By grinding the backside surface 2b until the grinding grooves 210 are exposed, the semiconductor wafer 2 is divided into the individual devices 22 as shown in FIG. 4C. Incidentally, the plurality of devices 22 thus divided are not separated away from each other and the form of the semiconductor wafer 2 is retained, since the protective member 4 is adhered to the face side of the devices 22.

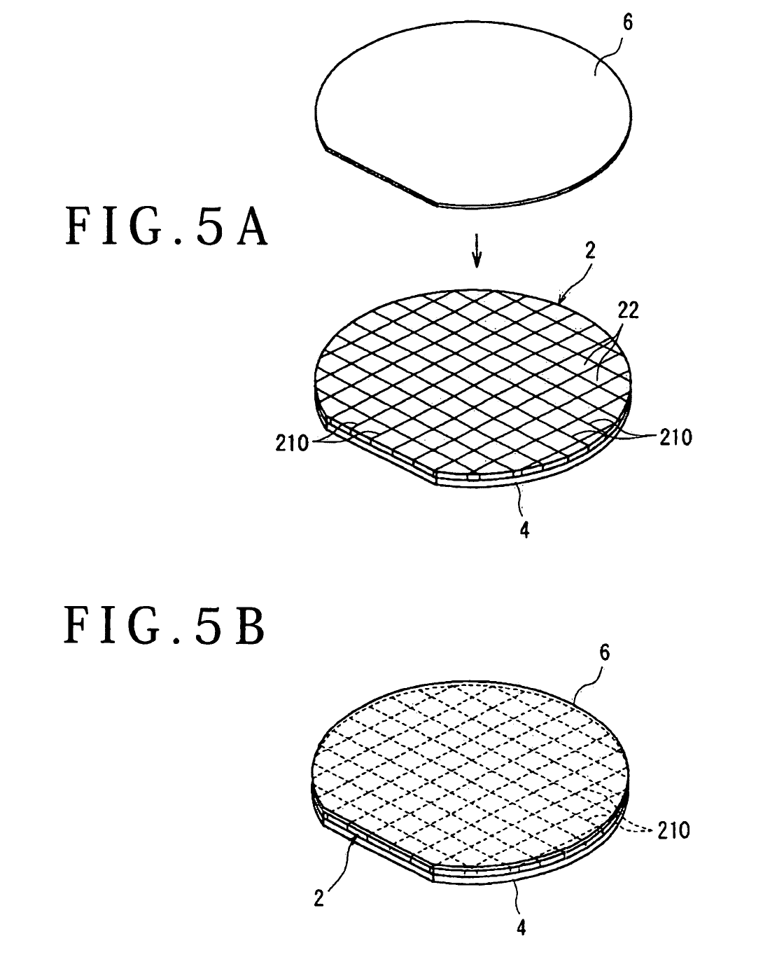

After the semiconductor wafer 2 is divided into the individual devices 22 by carrying out the wafer dividing step based on the dicing-before-grinding technique as above-mentioned, an adhesive film attaching step is conducted in which a die-bonding adhesive film to be cured by irradiation with UV rays is attached to the backside surface 2b of the semiconductor wafer 2 divided into the individual devices 22. Specifically, as shown in FIGS. 5A and 5B, the adhesive film 6 is attached to the backside surface 2b of the semiconductor wafer 2 divided into the individual devices 22. In this case, the adhesive film 6 is adhered by pressing it against the backside surface 2b of the semiconductor wafer 2 while heating it at a temperature of 80 to 200° C. as above-mentioned. Incidentally, as the adhesive film to be cured by irradiation with UV rays, for example, the adhesive film disclosed in Japanese Patent Laid-Open No. Hei 2-32181 can be used.

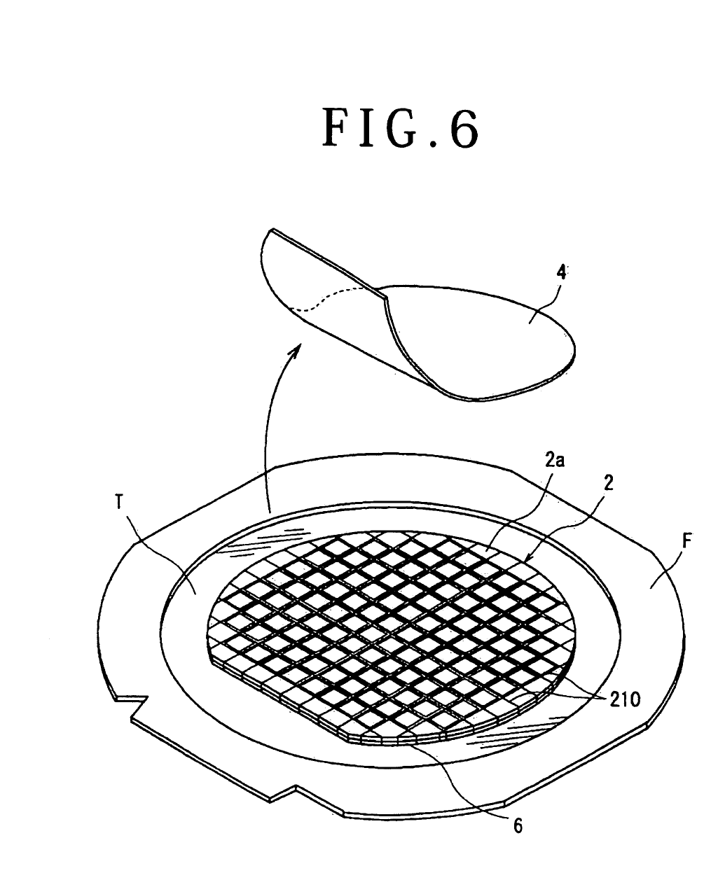

After the adhesive film attaching step is carried out as above-mentioned, a wafer supporting step is conducted in which the adhesive film 6 side of the semiconductor wafer 2 to which the adhesive film 6 has been attached is adhered to a surface of a dicing tape T attached to an annular frame F, as shown in FIG. 6. Then, the protective member 4 adhered to the face-side surface 2a of the semiconductor wafer 2 is peeled off (protective member peeling step). Incidentally, in the case of using a dicing tape with an adhesive film previously adhered to a surface thereof, the adhesive film adhered to the surface of the dicing tape is adhered to the backside surface 2b of the semiconductor wafer 2 divided into the individual devices 22 by carrying out the above-mentioned wafer dividing step. Then, the protective member peeling step as above-mentioned is carried out.

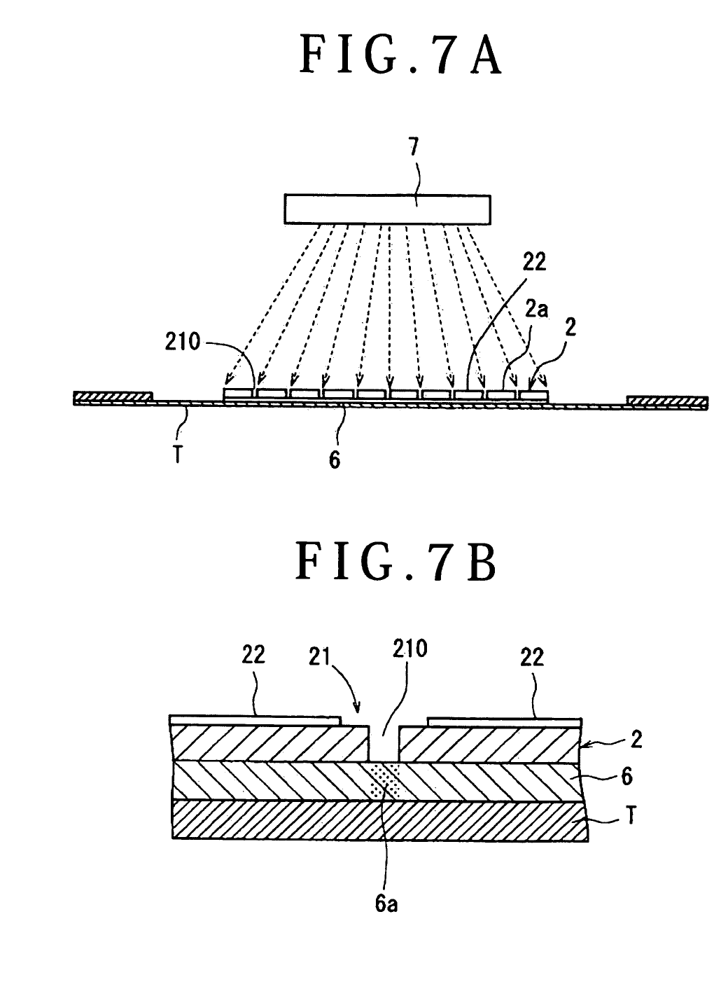

Next, an adhesive film curing step is carried out in which UV rays are radiated from the side of the face-side surface 2a of the semiconductor wafer 2 adhered to the dicing tape T attached to the annular frame F, so as to irradiate the adhesive film 6 with the UV rays through the dividing grooves 210 formed in the semiconductor wafer 2, thereby curing the regions of the adhesive film 6 which correspond to the dividing grooves 210. Specifically, the UV rays are radiated from the side of the face-side surface 2a of the semiconductor wafer 2 adhered to the dicing tape T attached to the annular frame F, by use of a UV ray irradiation apparatus 7 as shown in FIG. 7A. Incidentally, the UV ray irradiation apparatus 7 has a metal halide lamp, and radiates UV rays having a wavelength of 365 nm, a luminance of 40 mW/cm² and an illuminance of 200 mJ/cm² for 1 sec. As a result, the adhesive film is irradiated with the UV rays through the dividing grooves 210 formed in the semiconductor wafer 2, whereby the regions 6a of the adhesive film 6 which correspond to the dividing grooves 6 are cured as shown in FIG. 7B.

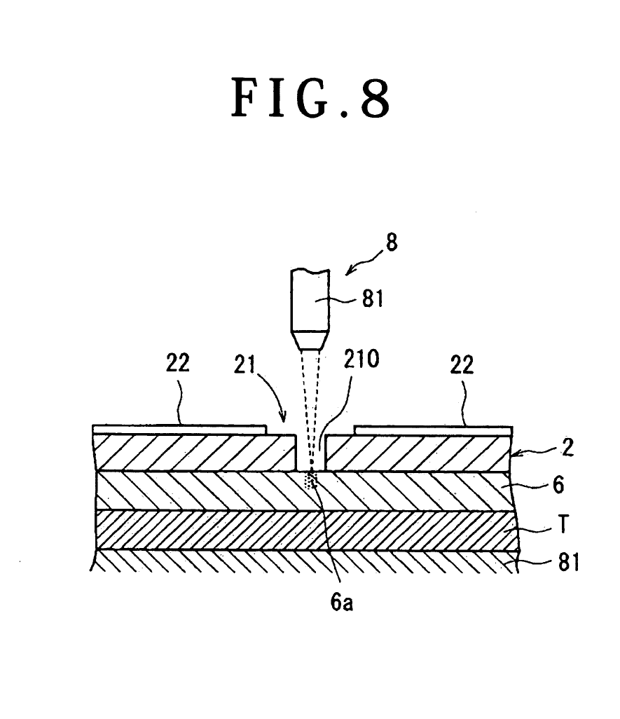

The adhesive film curing step as above can also be carried out by irradiation with a laser beam having a wavelength in the UV region. Specifically, as shown in FIG. 8, a pulsed laser beam is oscillated through a condenser 81 of a laser beam irradiation means 8 in the laser beam machining apparatus, so as to irradiate the adhesive film 6 with the pulsed laser beam through the dividing grooves 210 formed along the planned dividing lines 21 of the semiconductor wafer 2, whereby the regions 6a of the adhesive film 6 which correspond to the dividing grooves 210 are cured. Incidentally, the curing conditions in the adhesive film curing step in the laser beam machining are set, for example, as follows.
Kind of laser beam: LD-excited Q switch YAG laser
Wavelength: 355 nm
Repetition frequency: 100 kHz
Mean output: 0.3 W
Convergent spot diameter: φ15 μm
Machining feed speed: 100 mm/second

The adhesive film curing step as above-mentioned is carried out by use of a pulsed laser beam with an extremely low output of about 0.3 W, so that the adhesive film would not be melted, and no debris would be generated.

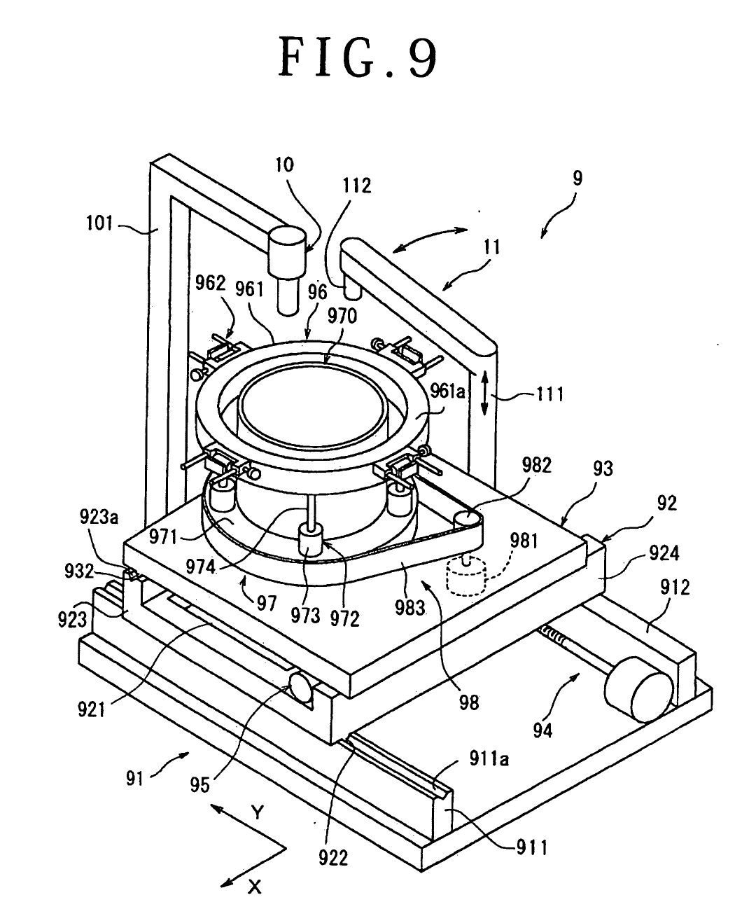

When the adhesive film curing step as above is conducted, an adhesive film splitting step in which the dicing tape is expanded to exert a tension on the adhesive film and to split the adhesive film along the individual devices, with the cured regions of the adhesive film as starting points of splitting, and a pick-up step in which the devices with the adhesive film split on the device basis being attached thereto are picked up by releasing them from the dicing tape are carried out. The adhesive film splitting step and the pick-up step are performed by use of a picking-up apparatus shown in FIG. 9. The picking-up apparatus 9 shown in FIG. 9 includes a base 91, a first table 92 disposed on the base 91 so as to be movable in the direction of arrow Y, and a second table 93 disposed on the first table 92 so as to be movable in the direction of arrow X which is orthogonal to arrow Y. The base 91 is formed in a rectangular shape, and two guide rails 911, 912 parallel to each other are disposed on upper surfaces of both side parts of the base 91 along the direction of arrow Y. Incidentally, one guide rail 911 of the two guide rails is provided in its upper surface with a guide groove 911a which is V-shaped in section.

The first table 92 is formed in the shape of a window frame provided in its central part with a rectangular opening 921. On a lower surface of one side part of the first table 92, a guided rail 922 is provided which is slidably fitted in the guide groove 911a formed in the one guide rail 911 provided on the base 91. In addition, two guide rails 923, 924 parallel to each other are disposed on upper surfaces of both side parts of the first table 92 along a direction orthogonal to the guided rails 922. Incidentally, one guide rail 923 of the two guide rails is provided in its upper surface with a guide groove 923a which is V-shaped in section. Of the first table 92 thus configured, the guided rail 922 is fitted in the guide groove 911a formed in the one guide rail 911 provided on the base 91, and the lower surface of the side part on the other side is mounted on the other guide rail 912. The picking-up apparatus 9 in the embodiment shown in the drawings has a first moving means 94 by which the first table 92 is moved in the direction of arrow Y along the guide rails 911, 912 provided on the base 91.

The second table 93 is formed in a rectangular shape. A guided rail 932 which is slidably fitted in the guide groove 923a formed in the one guide rail 923 provided on the first table 2 is provided on a lower surface of one side part of the second table 93. Of the second table 93 thus configured, the guided rail 932 is fitted in the guide groove 923a formed in the one guide rail 923 provided on the first table 92, and a lower surface of the other side part is mounted on the other guide rail 924 provided on the first table 92. The picking-up apparatus 9 in the embodiment shown in the figures has a second moving means 95 by which the second table 93 is moved in the direction of arrow X along the guide rails 923, 924 provided on the first table 92.

The picking-up apparatus 9 in the embodiment shown in the drawings includes a frame holding means 96 for holding the above-mentioned annular frame F, and a tape expanding means 97 for expanding the dicing tape T adhered to the annular frame F held by the frame holding means 97. The frame holding means 96 includes an annular frame holding member 961, and a plurality of clamps 962 provided as fixing means at the outer periphery of the frame holding member 961. An upper surface of the frame holding member 961 forms a mount surface 961a on which to mount the annular frame F, and the annular frame F is mounted on the mount surface 961a. The annular frame F mounted on the mount surface 961a is fixed to the frame holding member 961 by the clamps 962. The frame holding means 96 thus configured is disposed on the upper side of the second table 93, and is supported by the tape expanding means 97 (described later) so that it can be advanced and retracted in the vertical direction.

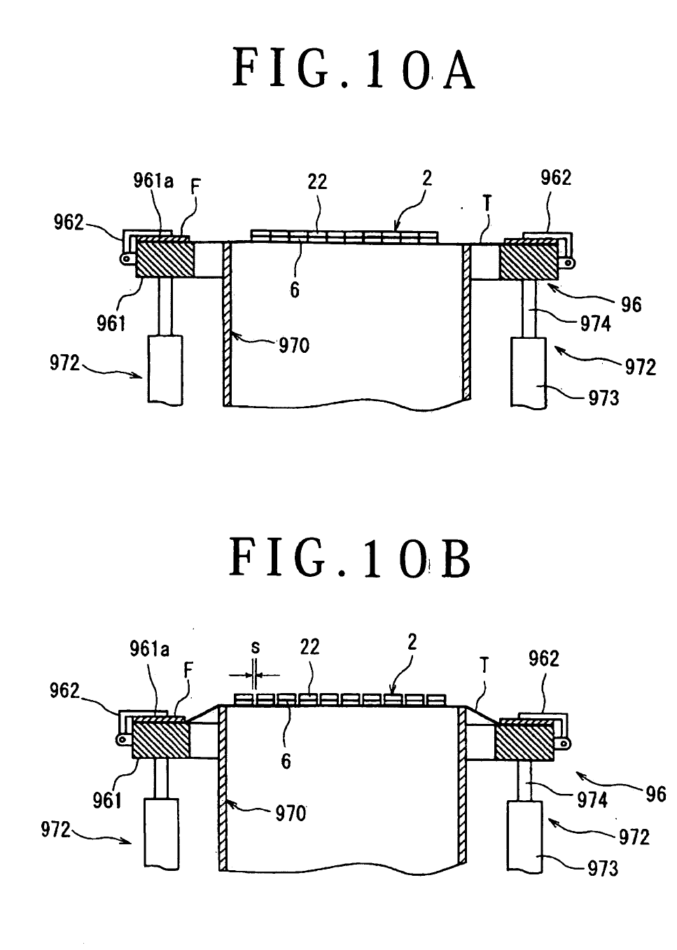

The tape expanding means 97 has an expansion drum 970 disposed on the inside of the annular frame holding member 961. The expansion drum 970 has an inside diameter and an outside diameter which are smaller than the inside diameter of the annular frame F and are greater than the outside diameter of the semiconductor wafer 2 adhered to the dicing tape T attached to the annular frame F. Besides, the expansion drum 970 is provided at its lower end part with an attaching part turnably fitted on the inner peripheral surface of a hole (not shown) provided in the second table 93, and is provided, at an outer peripheral surface on the upper side of the attaching part, with a support flange 971 formed to protrude in the radial direction. The tape expanding means 97 in the embodiment shown in the figures has a support means 972 by which the annular frame holding member 961 can be advanced and retracted in the vertical direction. The support means 972 includes a plurality of air cylinders 973 disposed on the support flange 971, and piston rods 974 of the air cylinders 973 are connected to a lower surface of the annular frame holding member 961. The support means 972 thus provided with the plurality of air cylinders 973 moves the annular frame holding member 961 selectively between a reference position in which the mount surface 961a of the annular frame holding member 961 is set at substantially the same height as the upper end of the expansion drum 970 as shown in FIGS. 9 and 10A and an expansion position in which the mount surface 961a of the annular frame holding member 961 is located a predetermined amount below the upper end of the expansion drum 970 as shown in FIG. 10B.

The picking-up apparatus 9 in the embodiment shown in the figures has a turning means 98 for turning the expansion drum 970 and the frame holding member 961, as shown in FIG. 9. The turning means 98 includes a pulse motor 981 disposed on the second table 93, a pulley 982 attached to a rotary shaft of the pulse motor 981, and an endless belt 983 wrapped around the pulley 982 and the support flange 971 of the expansion drum 970. The turning means 98 thus configured turns the expansion drum 970 by driving the pulse motor 981 and through the pulley 982 and the endless belt 983.

The picking-up apparatus 9 in the embodiment shown in the figures has a detecting means 10 for detecting the individually divided devices 22 of the semiconductor wafer 2 supported through the dicing tape T on the annular frame F held by the annular frame holding member 961. The detecting means 10 is attached to an L-shaped support column 101 disposed on the base 91. The detecting means 10 has an optical system and an imaging device (CCD) and the like, shoots (takes an image of) the individually divided device 22 of the semiconductor wafer 2 supported through the dicing tape T on the annular frame F held by the annular frame holding member 961, converts the image signal into an electrical signal, and sends the electrical signal to a control means (not shown).

In addition, the picking-up apparatus 9 in the embodiment shown in the drawings has a picking-up means 11 for picking up the individually divided device 22 from the dicing tape T. The picking-up means 11 includes a slewing arm 111 disposed on the base 91, and a pick-up collet 112 attached to the tip of the slewing arm 111, and the slewing arm 111 is driven to slew by a driving means (not shown). Incidentally, the slewing arm 111 is configured to be movable in the vertical direction, so that the pick-up collet 112 attached to its tip can pick up the individually divided device 22 adhered to the dicing tape T.

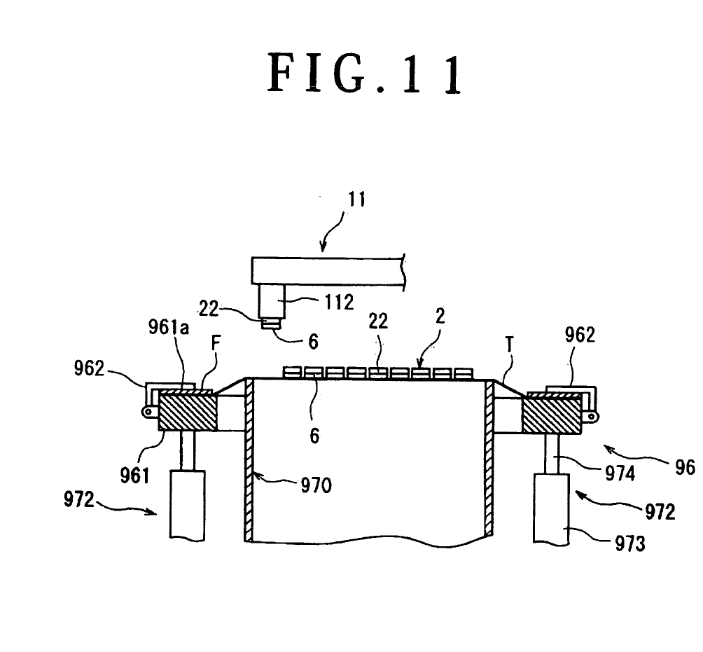

The picking-up apparatus 9 in the embodiment shown in the figures is configured as above, and an adhesive film splitting step and a pick-up step which are carried out by use of the picking-up apparatus 9 will be described below, referring mainly to FIGS. 10A to 11. The annular frame F supporting, through the dicing tape T, the individually divided devices 22 to which the adhesive film 6 having undergone the adhesive film curing step is attached is mounted on the mount surface 961a of the frame holding member 961 constituting the frame holding means 96 as shown in FIG. 10A, and the annular frame F is fixed to the frame holding member 961 by the clamps 962 (frame holding step). In this instance, the frame holding member 961 is positioned in the reference position shown in FIG. 10A.

After the annular frame F supporting, through the dicing tape T, the individual devices 22 each with the adhesive film 6 attached to the backside surface thereof is fixed to the frame holding member 961 positioned in the reference position as shown in FIG. 10A, the plurality of air cylinders 973 provided as the support means 972 constituting the tape expanding means 97 are operated so as to move the annular frame holding member 961 down to the expansion position shown in FIG. 10B. In this case, the annular frame F fixed to the mount surface 961a of the frame holding member 961 is also moved downwards, so that the dicing tape T attached to the annular frame F is brought into abutment on the upper end edge of the expansion drum 970 and expanded, as shown in FIG. 10B. Consequently, tensile forces are exerted in a radial manner on the adhesive film 6 adhered to the dicing tape T, so that the adhesive film 6 is split along the individual devices 22 through a process in which the regions 6a corresponding to the dividing grooves 210 and cured by the above-mentioned adhesive film curing step act as starting points of splitting (adhesive film splitting step). Then, gaps S between the individual devices 22 each with the adhesive film 6 attached thereto are broadened.

Thus, in the adhesive film splitting step, the dicing tape T to which the adhesive film 6 cured in the regions 6a corresponding to the dividing grooves 210 by the adhesive film curing step is adhered is expanded, so as to exert the tensile forces on the adhesive film 6a and to split the adhesive film 6 along the individual devices 22, with the cured regions 6a of the adhesive film 6 as starting points of splitting. Therefore, generation of debris as in the method of cutting the adhesive film 6 by irradiation with a laser beam is obviated. Accordingly, a lowering in the quality of devices 22 due to adhesion of debris to the face-side surfaces of the devices 22 can be precluded.

After the adhesive film splitting step is conducted as above-mentioned, the first moving means 94 and the second moving means 95 are operated to move the first table 92 in the direction of arrow Y (see FIG. 9) and to move the second table 93 in the direction of arrow X (see FIG. 9), and one of the individual devices 22 adhered through the adhesive film 6 to the dicing tape T attached to the annular frame F held by the frame holding member 961 is positioned in a position just under the detecting means 10. Then, the detecting means 10 is operated so as to check whether or not the gap between the individual devices 22 coincides with the direction of arrow Y or the direction of arrow X. If the gap between the individual devices 22 is deviated from the direction of arrow Y or the direction of arrow X, the turning means 98 is operated to turn the frame holding means 96, so as to obtain the desired coincidence.

Subsequently, while moving the first table 92 in the direction of arrow Y (see FIG. 9) and moving the second table 93 in the direction of arrow X (see FIG. 9), the picking-up means 11 is operated so as to attract by suction the device 22 (with the adhesive film 6 attached to the back-side surface thereof) positioned in a predetermined position by the pick-up collet 112 and to release the device 22 from the dicing tape T, thereby picking up the device 22 as shown in FIG. 11 (pick-up step), and the device 22 thus picked up is transported onto a tray (not shown) or to a die bonding step. In this pick-up step, the gaps S between the individual devices 22 to which the adhesive film 6 has been attached are broadened as above-mentioned, so that the device 22 can be easily picked up without contact with the adjacent device 22.

The present invention is not limited to the details of the above described embodiments. The scope of the invention is defined by the appended claims and all changes and modifications as fall within the equivalence of the scope of the claims are therefore to be embraced by the invention.

What is claimed is:

1. A method of manufacturing a device, for dividing a wafer provided with devices formed in a plurality of regions demarcated by planned dividing lines formed in a lattice pattern in a face-side surface, into individual devices, said method comprising:
a wafer dividing step of forming dividing grooves in a predetermined depth along said planned dividing lines from the face side of said wafer, then grinding a backside surface of said wafer to expose said dividing grooves on the back side of said wafer and dividing said wafer into said individual devices;
an adhesive film attaching step of attaching a UV-curing adhesive film for die-bonding to said backside surface of said wafer divided into said individual devices;
a wafer supporting step of adhering the adhesive film side of said wafer with said adhesive film attached to a surface of a dicing tape attached to an annular frame;
an adhesive film curing step of radiating UV rays from the face side of said wafer adhered to said dicing tape so as to irradiate said adhesive film with said UV rays through said dividing grooves formed in said wafer and to cure those regions of said adhesive tape which correspond to said dividing grooves;
an adhesive film splitting step of, after said adhesive film curing step, expanding said dicing tape so as to exert a tension on said adhesive film and to split said adhesive film along said devices, with said cured regions of said adhesive film as starting points of splitting; and
a pick-up step of, after said adhesive film splitting step, releasing from said dicing tape, and picking up, each said device to which said adhesive tape divided on the device basis has been attached.
